(19) United States
(12) Patent Application Publication
(10) Pub. No.: US 2010/0042885 A1
(43) Pub. Date: Feb. 18, 2010

(54) Method and Apparatus for Maximizing Wireless Bandwidth During Ad Transmission with Forward Error Correction (FEC)

(76) Inventors: Srinivasa Dharmaji, Cupertino, CA (US); Xin Feng, Basking Ridge, NJ (US)

Correspondence Address: GLENN PATENT GROUP, 3475 EDISON WAY, SUITE L, MENLO PARK, CA, 94025, US

(21) Appl. No.: 12/539,878

(22) Filed: Aug. 12, 2009

Related U.S. Application Data
(60) Provisional application No. 61/189,106, filed on Aug. 15, 2008.

(51) Int. Cl. H04L 1/18; H03M 13/05; G06F 11/10; G06F 11/14; G06Q 30/00

(52) U.S. Cl. 714/748; 714/752; 705/14.64; 714/E11.032; 714/E11.113

(57) ABSTRACT

The number of times a single ad file must be sent for reception by a plurality of mobile hand held devices (MHDDs) without any error is reduced by the use of forward error correction (FEC) to achieve statistical coverage of a complete ad file download

### CROSS REFERENCE TO RELATED APPLICATIONS

This application claims priority to U.S. provisional patent application Ser. No. 61/189,106, filed 15 Aug. 2008, which application is incorporated herein in its entirety by this reference thereto.

### BACKGROUND OF THE INVENTION

1. Technical Field

The invention relates to a system for using the available broadcast bandwidth more effectively for transmission of multiple advertisements to hand held display units. More particularly, the invention relates to a method and apparatus for maximizing wireless bandwidth during ad transmission with forward error correction (FEC).

2. Description of the Prior Art

Wireless spectrum is becoming very crowded because it is increasingly used as a transmission medium for more and more applications. Transmission of advertisements to mobile handheld display devices (MHDDs) is one such application. The limitation in spectrum availability becomes more acute when multiple ads are to be transmitted to different target groups simultaneously. Multiple transmission of the same file containing the advertisement is required to ensure proper reception by at least a high percentage, if not all, of the MHDDs that are selected to receive the advertisement. This consumes considerable bandwidth.

FIG. 1 is a block schematic diagram that shows a prior art method of transmitting full and correct data to an acceptable percentage of an MHDD user population. In FIG. 1, a system 100 includes an ad file transmitting unit 103 and a mobile hand held device (MHDD) 193. FIG. 1 shows a first transmission sequence 110, a second transmission sequence 120, and an n^{th} transmission sequence 1n0. Advertisements (ads) to be displayed on MHDDs during viewing of content are transferred to such MHDDs during slack time, when the spectrum is not busy. These ads are downloaded and stored by the MHDD, and are then selectively rendered during available advertisement spots (ad spots) while the user is viewing content on the MHDD.

In FIG. 1, the ad file 101 to be sent over the broadcast medium is broken down into small packets 102. The transmitting unit 103 transmits these small packets over the wireless medium 110 as a file 105 that contains a plurality of packets 106. The packets in the file 105 are transmitted sequentially. An end-of-file (EOF) notification is added to the last packet to indicate to the targeted MHDDs that the file is complete. A checksum is also provided to check if all the packets are received correctly.

Although most of the MHDDs receive the packets intact, along with the checksum and EOF notification, there are typically a few units that do not receive one or two packets. These packets are lost in transmission. For example, in the ad file 115, a packet 117 is lost. All other packets 116 are received by the MHDD 193. Upon storing and verifying the checksum on the received packets 192, the MHDD 193 recognizes that the file 191 is incomplete and faulty because a packet 197 is missing or corrupted.

Current practice is for the MHDD 193 to discard all of the received packets 192 and the corrupted file 191 without storing them. There are usually many MHDDs in a typical system that are widely separated geographically. If each of the MHDDs that did not receive the full complement of packets provided feedback to this effect, then the spectrum would become very crowded. Instead, the current practice is for the unit transmitting the ad to re-transmit the whole file 101 again. In second transmission, another packet 197 may be lost, as shown in FIG. 1. It then becomes necessary to transmit the file 101 again and again until statistically it can be assured that the complete and correct file 191 has reached almost all of MHDDs for download and store.

Thus, as is shown in FIG. 1, a large number of transmissions of the file 101, i.e. “N” transmissions, are typically required for the file 191 to be downloaded correctly to a statistically acceptable percentage of selected MHDDs. The multiple retransmissions are expensive in terms of bandwidth use. This is especially true when a number of targeted ads have to be transmitted and downloaded within the limited bandwidth provided.

In view of the limitations of prior are it would be therefore advantageous if the number of times the file has to be transmitted could be reduced, while retaining the statistical coverage for complete file download by the selected MHDDs.

### SUMMARY OF THE INVENTION

An embodiment of the invention reduces the number of times a single ad file must be sent for reception by a plurality of MHDDs without any error. A presently preferred embodiment provides a method and apparatus that uses forward error correction (FEC) to achieve statistical coverage of a complete ad file download with a reduced number of transmissions of the ad file over the wireless medium, when compared to that of the prior art.

### BRIEF DESCRIPTION OF THE DRAWINGS

FIG. 1 is a block schematic diagram that shows a prior art method of transmitting full and correct data to an acceptable percentage of a MHDD user population;

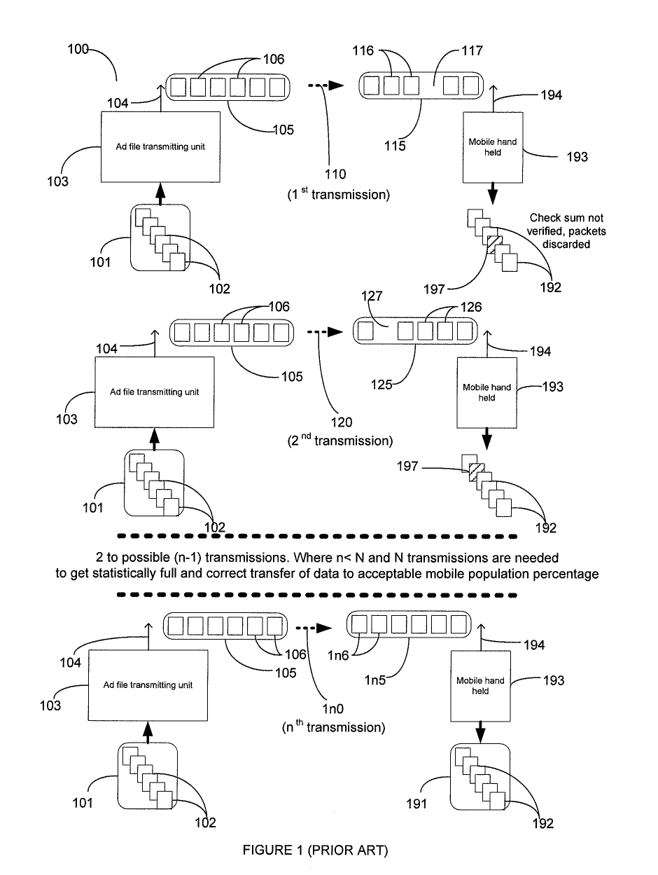

FIG. 2 is a block schematic diagram that shows a system for transferring data to an acceptable percentage of a MHDD user population by using selective fills of missing packets according to an embodiment of the invention; and

FIG. 3 is a flow diagram that shows the operation of a system for transferring data to an acceptable percentage of a MHDD user population with change to all packets according to an alternate embodiment of the invention.

### DETAILED DESCRIPTION OF THE INVENTION

An embodiment of the invention reduces the number of times a single ad file must be sent for reception by a plurality of MHDDs without any error. A presently preferred embodiment provides a method and apparatus that uses forward error correction (FEC) to achieve statistical coverage of a complete ad file download with a reduced number of transmissions of the ad file over the wireless medium, when compared to that of the prior art.

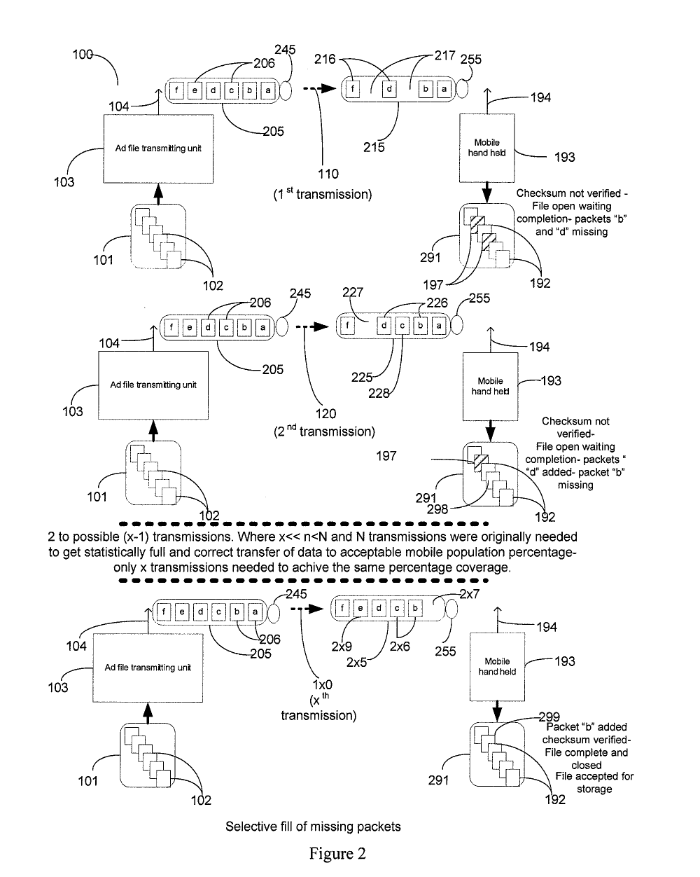

FIG. 2 is a block schematic diagram that shows a system for transferring data to an acceptable percentage of a MHDD user population by using selective fills of missing packets according to an embodiment of the invention. The ad is first divided into a number of data packets. The data packets are generated by breaking the ad up to form an ad file. Each sequential data packet in the ad file is provided with a metadata sequence identifier. The packets with a sequence identifier are shown in FIG. 2 as packets ‘a’ to ‘f.’ The transmitted ad file 205, containing data packets ‘a’ to ‘f,’ is preceded by a packet 245, which contains additional information-metadata which indicates the ad file identification (ID), the number of data packets (#) of which the ad is comprised, and the checksum for all data packets in the ad (CS). The last packet contains an end-of-file (EOF) notification. When an MHDD 193 receives and downloads the metadata packet 255, it creates a temporary ad storage file (ASF) 291 that has the correct number of data packet locations for packets ‘a’ to ‘f.’ The transmitted data packets 206 of ad file 205 are received by the MHDD 193, but the received file 215 may or may not have all the packets that were sent. When the EOF notification is received, the MHDD 193 checks the ASF for missing packets in the assigned locations. It recognizes that some data packets, for example ‘c’ and ‘e’ 197, are missing in the first transmission. Instead of discarding the whole ASF 291 as in the prior art, the MHDD keeps the ASF 291 open until the missing data packets 197 are received for an ad subsequently retransmitted from source 103. The retransmissions are based on statistical calculations for full reception by all selected MHDDs.

In FIG. 2, the second transmission provides the data packet with an identifier ‘c’ 228. This is accepted and stored 298 at the MHDD. A check for missing packets indicates that a packet ‘e’ 227 is still missing after the second transmission. The process is repeated until the missing data packet ‘e’ 2x9 is received in the ‘x’th transmission of the ad file. This data packet is transferred, as indicated by numeric designator 299, to the open ASF 291. The open ASF 291 is then complete and the checksum CS is verified on the ASF. If the CS is correct, the ASF 291 is closed and the extracted ad, compiled from data packets without the associated metadata, is accepted for storage on the MHDD 193. In this case, the MHDD looks for only the missing data packets during reception of the ad file, and not for the fully transmitted file. Hence, the probability of the same data packets not reaching any selected MHDD in ‘x’ transmissions of the ad file, where x<<N, is small. Using this type of FEC, the number of times x that the ad file must be re-transmitted to achieve the full ad reception by selected MHDDs is reduced. If the number of times that retransmission must be performed to effect correct ad reception by all selected MHDDs of all transmitted packets in any one transmission is N, then the number of retransmissions needed when FEC is used is much less than N. Hence, the number of planned retransmissions can be reduced. This allows more ads to be transmitted to, and stored in, the MHDDs over the same available bandwidth.

An alternative embodiment of the invention uses FEC to achieve statistically acceptable ad download quality, where the MHDDs which have an open ASF 291 continue to download and replace the existing data packets with all the data packets that are received in each transmission from the source 103. Accordingly, previously received data packets are replaced with newly received data packets when the ASF 291 is open, leaving the rest of the previously received data packets in the ASF 291 intact. That is, wherever a set of new data packets is received, the newly received packets replace the data packets previously received, and the newly received data packets are stored in the ASF 291. Already received data packets that are stored in ASF 291 at locations where there are any missing data packets in the newly received file are retained untouched, thereby filling up the ASF 291. At the end of each reception, the file is checked for missing packets. If any data packets are missing, the ASF 291 is kept open for the next reception of the ad file. Once all data packets have been received, the ASF 291 is closed. The file is then verified with a checksum to see if the data packets are complete and correct. When the ASF 291 is verified to be correct, the ad is extracted and stored in the MHDD for future use. In this case, there is no need to search for specific packets to download and insert into the file. This method also provides a similar statistical probability of achieving complete coverage as in the case of the use of FEC with selective insertion, as discussed above. This allows a reduction in the number of retransmissions and, hence, improves bandwidth use.

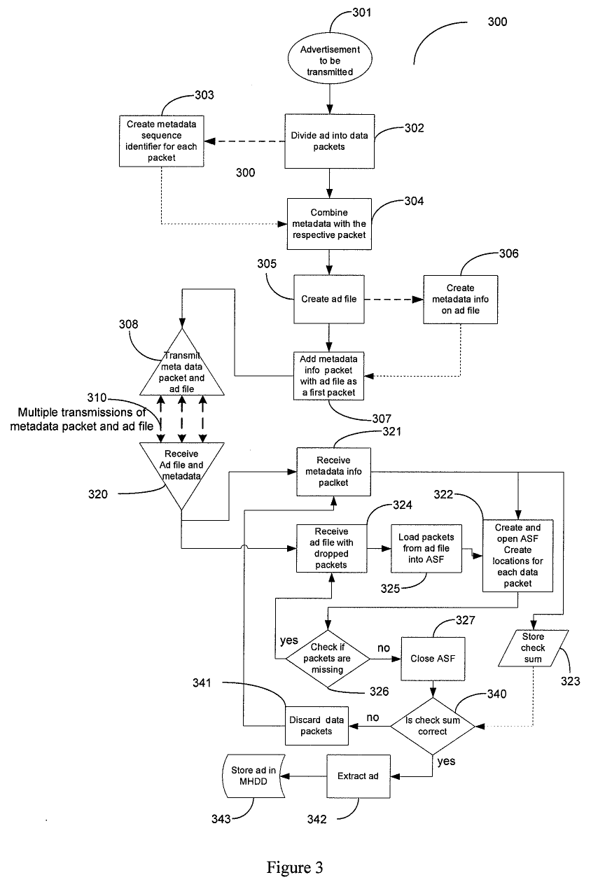

FIG. 3 is a flow diagram that shows the operation of a system for transferring ads to an acceptable percentage of a MHDD user population with changes to all packets according to an alternate embodiment of the invention. The ad to be transmitted 301 is divided into multiple data packets 302. A metadata sequence identifier 303 is created for each data packet 302 generated and is associated with the data packet 304. An ad file is created which consists of the data packets that are to be transmitted 305. A metadata packet 306 containing information on the ad file is created 306 and is attached to the ad file as a first packet 307. The metadata packet and the ad file are transmitted 308. The last packet to be transmitted also contains and end-of-file (EOF) notification. Multiple transmissions 310 of the metadata and ad file 307 are performed to ensure full reception of the ad by all of the selected MHDDs.

For example, the MHDD receives the transmission 320, possibly with some dropped packets. The metadata packet 321 opens an ASF file and establishes a sequential location for all data packets that are to be received 322. The checksum is stored for later use 323. The ad file is received 324 and the data packets available are loaded into the ASF 325. The ASF is checked to see if all packets have been received 326. If all packets have not been received, the process is repeated by updating the ASF from the next ad file received. If all files have been received, the ASF is closed 327. The closed ASF is checked for correctness using the checksum 340 and, if it is found to be incorrect, the respective data packets are discarded 341 and the process of opening a new ASF is repeated. Otherwise, if the closed ASF is found to be correct, the ad is extracted 342 and stored for use by the MHDD 343.

Once the ads are downloaded to, and stored on the MHDDs, they are inserted into the correct ad spots during content viewing. A generic method for inserting stored ads into an MHDD is provided in the co-pending patent application Ser. No. 11/828,204, filed Jul. 25, 2007, Micro-Splicer For Inserting Alternate Content To A Content Stream On A Handheld Device, which application is assigned to a common assignee, and which application is incorporated herein in its entirety by this reference thereto.

The use of the FEC techniques taught herein reduces the number of times an ad must be transmitted for the selected MHDDs to download and store the ads. The additional bandwidth and time made available can be used to download more ads into the MHDDs.

Even though two exemplary FEC embodiments are described herein, this is not meant to be limiting in any way. The invention may be practiced with other sequences and features which will be understood by practitioners of the art. Such approaches to using the herein disclosed FEC for improving the bandwidth use during content and ad transfer to MHDDs are all covered by this disclosure.

Although the invention is described herein with reference to the preferred embodiment, one skilled in the art will readily appreciate that other applications may be substituted for those set forth herein without departing from the spirit and scope of the present invention. Accordingly, the invention should only be limited by the Claims included below.

1. A method for transmitting an advertisement (ad) to a plurality of mobile handheld display devices (MHDDs), comprising the steps of:
breaking the ad to be transmitted into a sequence of data packets;
generating and associating a sequence identifier metadata with each data packet of said sequence of data packets;
storing said sequence of data packets in an ad file;
generating a metadata packet containing at least an ad file identifier (ID), a count (#) of data packets contained in said ad file, and a checksum (CS) of all data packets in said ad file;
storing said metadata packet as a first packet of said ad file;
transmitting said ad file to a plurality of MHDDs a plurality of times; and
at an MHDD receiving data packets from said ad file, applying forward error correction (FEC) to verify correct reception of said data packets.

2. A method for improving bandwidth use during advertisement (ad) reception by a mobile handheld display device (MHDD), comprising the steps of:
receiving a first metadata packet, said metadata packet containing metadata respective of an ad file, said metadata packet containing at least an ad file identification (ID), a count (#) of data packets contained in said ad file, and a checksum (CS) for all data packets in said ad file;
opening an advertisement storage file having said ID and having a corresponding number of sequential locations for storage of said # of data packets of said ad file;
storing said checksum in a storage for error checking of said data packets;
receiving said ad file with some or all of said data packets;
placing said data packets in their respective sequential location in said storage based on a metadata attached to each of said data packets;
checking content stored in said storage for any missing data packets at any of said sequential locations;
keeping said storage open for a reception of a retransmission of said ad file if missing data packets are detected;
checking a subsequently received ad file for said missing data packets;
downloading and inserting any of said missing data packets in a respective sequential location from said subsequently received ad file;
repeating a sequence of checking, downloading, and inserting said missing data packets until substantially all said sequential locations in said storage are filled;
closing said storage;
verifying content of said storage using said checksum and, if correct, then extracting said ad file from said storage; otherwise, repeating reception of said ad file; and
storing said received ad file;
wherein a correctly verified ad is received and stored using a lower number of retransmissions and receptions of said ad file, thereby improving bandwidth use during ad transmission to said MHDD.

3. In a method for using a metadata packet as a first packet of an ad file consisting of information in the ad file, said metadata packet comprising an ad file identification (ID), a count (#) of data packets contained in said ad file, and a checksum (CS) for all data packets in said ad file, the method comprising the step of:
using said metadata packet to provide forward error correction during transmission to, and reception of, said ad file at a mobile hand held device (MHDD).

4. A method for using a metadata sequence identifier associated with each data packet of a transmitted ad file, comprising the steps of:
using said metadata sequence identifier to enable a receiver to store each said data packet in a correct sequence; and
using said metadata sequence identifier to identify any missing packets in said transmitted ad file for forward error correction.

5. A method for transferring an ad to an acceptable percentage of members of a mobile hand held device (MHDD) user population by using selective fills for missing packets in an ad file, comprising the steps of:
dividing said ad into a number of sequential data packets to form an ad file;
providing each sequential data packet in the ad file with a metadata sequence identifier comprising information-metadata which indicates the ad file identification (ID), a number of data packets (#) of which the ad is comprised, and a checksum for all data packets in the ad (CS), wherein a last packet contains an end-of-file (EOF) notification;
receiving and downloading a metadata packet;
creating a temporary ad storage file (ASF) that has a correct number of data packet locations for all packets in said ad file;
receiving transmitted data packets of said ad file;
when the EOF notification is received, checking the ASF for missing packets in assigned locations; and
if any data packets are missing in a first transmission, keeping the ASF open until the missing data packets are received for an ad subsequently retransmitted, wherein said retransmission is based upon statistical calculations for full reception by all selected MHDDs.

6. The method of claim 5, further comprising the steps of:
after each subsequent transmission, checking for missing packets; and
repeating said transmission and checking steps until each missing data packet is received.

7. The method of claim 5, further comprising the steps of:
transferring received data packets to said ASF;
when all data packets are received and said ASF is complete, verifying the checksum CS on the ASF; and
if the CS is correct, closing the ASF, extracting the ad, and storing said ad on the MHDD.

8. The method of claim 5, further comprising the steps of:
continuing to download and replace all existing data packets within an ASF with all the data packets that are received in each subsequent transmission;
replacing previously received data packets with corresponding newly received data packets when the ASF is open, leaving the rest of the previously received data packets in the ASF intact;
wherein wherever a set of new data packets is received, the newly received packets replace the data packets previously received, and the newly received data packets are stored in the ASF;
wherein already received data packets that are stored in the ASF at locations where there are any missing data packets in a newly received file are retained untouched, thereby filling up the ASF;
at the end of each reception, checking the file for missing packets;
if any data packets are missing, keeping the ASF open for the next reception of the ad file; and
once all data packets have been received, closing the ASF, verifying the file with a checksum to determine if the data packets are complete and correct, and if the ASF is verified to be correct, extracting and storing the ad for future use.

9. A computer readable storage medium containing computer readable instructions for operating a processor to execute a program for performing the steps of any of claims 1-8.

10. An apparatus for transmitting an advertisement (ad) to a plurality of mobile handheld display devices (MHDDs), comprising:
an ad file transmitting unit for breaking the ad to be transmitted into a sequence of data packets;
said ad file transmitting unit generating and associating a sequence identifier metadata with each data packet of said sequence of data packets;
said ad file transmitting unit storing said sequence of data packets in an ad file;
said ad file transmitting unit generating a metadata packet containing at least an ad file identifier (ID), a count (#) of data packets contained in said ad file, and a checksum (CS) of all data packets in said ad file;
said ad file transmitting unit storing said metadata packet as a first packet of said ad file;
said ad file transmitting unit transmitting said ad file to a plurality of MHDDs a plurality of times; and
said MHDD receiving data packets from said ad file, applying forward error correction (FEC) to verify correct reception of said data packets.

11. An apparatus for improving bandwidth use during advertisement (ad) reception by a mobile handheld display device (MHDD), comprising:
said MHDD configured for receiving a first metadata packet, said metadata packet containing metadata respective of an ad file, said metadata packet containing at least an ad file identification (ID), a count (#) of data packets contained in said ad file, and a checksum (CS) for all data packets in said ad file;
said MHDD configured for opening an advertisement storage file having said ID and having a corresponding number of sequential locations for storage of said # of data packets of said ad file;
said MHDD configured for storing said checksum in a storage for error checking of said data packets;
said MHDD configured for receiving said ad file with some or all of said data packets;
said MHDD configured for placing said data packets in their respective sequential location in said storage based on a metadata attached to each of said data packets;
said MHDD configured for checking content stored in said storage for any missing data packets at any of said sequential locations;
said MHDD configured for keeping said storage open for a reception of a retransmission of said ad file if missing data packets are detected;
said MHDD configured for checking a subsequently received ad file for said missing data packets;
said MHDD configured for downloading and inserting any of said missing data packets in a respective sequential location from said subsequently received ad file;
said MHDD configured for repeating a sequence of checking, downloading, and inserting said missing data packets until substantially all said sequential locations in said storage are filled;
said MHDD configured for closing said storage;
said MHDD configured for verifying content of said storage using said checksum and, if correct, then extracting said ad file from said storage; otherwise, repeating reception of said ad file; and
said MHDD configured for storing said received ad file;
wherein a correctly verified ad is received and stored using a lower number of retransmissions and receptions of said ad file, thereby improving bandwidth use during ad transmission to said MHDD.

12. In an apparatus for using a metadata packet as a first packet of an ad file consisting of information in the ad file, said metadata packet comprising an ad file identification (ID), a count (#) of data packets contained in said ad file, and a checksum (CS) for all data packets in said ad file, the apparatus comprising:
means configured for using said metadata packet to provide forward error correction during transmission to, and reception of, said ad file at a mobile hand held device (MHDD).

13. An apparatus for using a metadata sequence identifier associated with each data packet of a transmitted ad file, comprising:
a processor configured for using said metadata sequence identifier to enable a receiver to store each said data packet in a correct sequence; and
said processor configured for using said metadata sequence identifier to identify any missing packets in said transmitted ad file for forward error correction.

14. An apparatus for transferring an ad to an acceptable percentage of members of a mobile hand held device (MHDD) user population by using selective fills for missing packets in an ad file, comprising:
an ad file transmitting unit for dividing said ad into a number of sequential data packets to form an ad file;
said ad file transmitting unit providing each sequential data packet in the ad file with a metadata sequence identifier comprising information-metadata which indicates the ad file identification (ID), a number of data packets (#) of which the ad is comprised, and a checksum for all data packets in the ad (CS), wherein a last packet contains an end-of-file (EOF) notification;
said MHDD configured for receiving and downloading a metadata packet;
said MHDD configured for creating a temporary ad storage file (ASF) that has a correct number of data packet locations for all packets in said ad file;
said MHDD configured for receiving transmitted data packets of said ad file;
said MHDD configured for checking the ASF for missing packets in assigned locations when the EOF notification is received; and
said MHDD configured for keeping the ASF open until the missing data packets are received for an ad subsequently retransmitted if any data packets are missing in a first transmission, wherein said retransmission is based upon statistical calculations for full reception by all selected MHDDs.

15. The apparatus of claim 14, further comprising:
said MHDD configured for checking for missing packets after each subsequent transmission; and
said MHDD configured for repeating said checking until each missing data packet is received.

16. The apparatus of claim 14, further comprising:
said MHDD configured for transferring received data packets to said ASF;
said MHDD configured for verifying the checksum CS on the ASF when all data packets are received and said ASF is complete; and
said MHDD configured for closing the ASF, extracting the ad if the CS is correct, and storing said ad.

17. The apparatus of claim 14, further comprising:
said MHDD configured for continuing to download and replace all existing data packets within an ASF with all the data packets that are received in each subsequent transmission;
said MHDD configured for replacing previously received data packets with corresponding newly received data packets when the ASF is open, leaving the rest of the previously received data packets in the ASF intact;
wherein wherever a set of new data packets is received, the newly received packets replace the data packets previously received, and the newly received data packets are stored in the ASF;
wherein already received data packets that are stored in the ASF at locations where there are any missing data packets in a newly received file are retained untouched, thereby filling up the ASF;
said MHDD configured for checking the file for missing packets at the end of each reception;
said MHDD configured for keeping the ASF open for the next reception of the ad file if any data packets are missing; and
said MHDD configured for closing the ASF once all data packets have been received, verifying the file with a checksum to determine if the data packets are complete and correct, and if the ASF is verified to be correct extracting and storing the ad for future use.
